(19) United States
(12) Patent Application Publication
(10) Pub. No.: US 2010/0224229 A1
(43) Pub. Date: Sep. 9, 2010

(54) MULTI-JUNCTION SEMICONDUCTOR PHOTOVOLTAIC APPARATUS AND METHODS

(76) Inventors: Martin U. Pralle, Wayland, MA (US); James E. Carey, Waltham, MA (US)

Correspondence Address: PEPPER HAMILTON LLP, ONE MELLON CENTER, 50TH FLOOR, 500 GRANT STREET, PITTSBURGH, PA, 15219, US

(21) Appl. No.: 12/720,214

(22) Filed: Mar. 9, 2010

Related U.S. Application Data
(60) Provisional application No. 61/158,567, filed on Mar. 9, 2009.

(51) Int. Cl. H01L 31/042; H01L 31/00

(52) U.S. Cl. 136/244; 136/256

(57) ABSTRACT

A multi-junction thin film semiconductor photovoltaic devices having improved absorption properties and increased efficiencies and methods for making the same are disclosed.

### RELATED APPLICATIONS

This application claims the benefit and priority of provisional patent application Ser. No. 61/158,567 filed on Mar. 9, 2009, all of which is hereby incorporated by reference.

### TECHNICAL FIELD

The present disclosure relates to the manufacture of photovoltaic devices. More specifically the present invention is drawn towards thin film photovoltaic devices.

### BACKGROUND

The advantages of thin film solar cells over “thick” cells include reduced material cost, large area and complete module processing, and the ability to be fabricated on flexible and transparent substrates. However, to date, most thin-film technologies have lower efficiencies as compared to thick substrates. The efficiency loss is mainly attributed to absorption losses and crystalline defects. Reduced cost but lower efficiency becomes a hurdle to competing in large-scale power generation applications where there are surface area constraints and installation costs dominate the overall cost structure.

The most common material groups used in thin-film solar cells are silicon (amorphous and polycrystalline), cadmium indium diselenide (CIS and CIGS if gallium is included), and cadmium telluride (CdTe). For exemplary discussion we will discuss the background of thin-film silicon solar cells, but the advantages of laser processing described herein can be extended to other thin-film material systems.

Amorphous silicon and microcrystalline thin films are typically grown/deposited using chemical vapor deposition on a transparent substrate such as glass or a flexible plastic. The semiconductor component of silicon thin film solar cells is typically a few microns in thickness, as compared to hundreds of microns for thick solar cells. The savings in raw material provides an economic advantage and these types of thin film devices save on raw silicon material usage over traditional thick cells because they have much higher absorption efficiency. In addition, the reduction in processing steps and the ability to make entire solar cell modules on one substrate offer significant manufacturing and cost advantages. However, thin-films struggle with a tradeoff of needing enough thickness to absorb sufficient light, and reduced carrier collection efficiency as the semiconductor layers get thicker. Mobilities are often lower in these devices so a strong field and a short travel distance for photocarriers is critical for high efficiency. In addition, growing a thicker film takes more manufacturing time, more material, adds stress, and at some thickness becomes impractical.

The external quantum efficiency (EQE) of a photovoltaic device is the current obtained outside the device per incoming photon. The external quantum efficiency therefore depends on both the absorption of light and the collection of charges. The “external” quantum efficiency of a silicon solar cell includes the effect of optical losses such as transmission and reflection. “Internal” quantum efficiency refers to the efficiency with which photons that are not reflected or transmitted out of the cell can generate collectable carriers. By measuring the reflection and transmission of a device, the external quantum efficiency curve can be corrected to obtain the internal quantum efficiency curve.

$$\begin{matrix}EQE = \frac{\frac{electrons}{sec}}{\frac{photons}{sec}} \\ = \frac{\frac{current}{charge of 1 electron}}{\frac{total power of photons}{energy of one photon}}\end{matrix}$$

In the case of amorphous silicon the band gap is such that light beyond 750 nm is not absorbed (as compared to 1100 nm for thick crystalline silicon). The solar spectrum has more than 50% of its energy in wavelengths longer than 750 nm. Therefore a very large portion of the solar spectrum is not converted to electricity in thin-film amorphous solar cells. A recent approach to improve the performance at longer wavelengths is to add a second solar cell junction beneath the first junction to create a stacked multi-junction solar cell where each junction is tuned to a specific part of the solar spectrum. In this way, light that is not captured by the top cell, transmits through the top cell and is absorbed by the second cell beneath. This of course can be extended to a plurality of cells specifically designed to collect multiple wavebands of solar radiation. The solar cell junction referred to above is the boundary interface where the two regions of the semiconductor device meet and a depletion region is formed. The two regions of the semiconductor device are often formed by doping.

### SUMMARY

From the discussion given above it can be appreciated that better photovoltaic devices are desirable. The following discussion provides such improved apparatus and methods of manufacture of the apparatus. Embodiments hereof provide a method of using laser processing to create at least one absorbing layer within a multi-junction thin film silicon solar cell that increases the long wavelength light efficiency. More specifically, the present invention uses a short pulse laser processing system to create a plurality of absorbing layers in a tandem junction micromorph thin film semiconductor photovoltaic device that has an increase wavelength response. The present invention can have enhanced quantum efficiency at long wavelengths and the high absorption properties can lead to greater than about 15% efficiency in a thin film photovoltaic device.

The combination of high quantum efficiency thin film silicon for short wavelengths and the high quantum efficiency of laser processed silicon for longer wavelengths enables a new type of photovoltaic device that has low material costs and significantly enhanced conversion efficiency. In some cases, the efficiency can be greater than about 5%. In other embodiments the efficiency can be greater than about 10% or even greater than about 15%. In addition, the present photovoltaic device can utilize silicon as a semiconductor material and thereby reduce cost compared to other traditional thin film cell types such as cadmium telluride and copper indium gallium diselenide and does not require the use of toxic materials. Although, silicon is preferred, these and other materials can be used to achieve similar results.

The use of silicon type material, combination photovoltaic devices can take advantage of the strengths of current thin-film silicon photovoltaic devices and enhances the performance at longer wavelengths by using high quantum efficiency laser processed silicon as an absorbing semiconductor layer, i.e. a backstop for light. The wavelengths detectable by the present invention may be in the range of about 400 nm to about 1300 nm.

In one embodiment of the present invention, a photovoltaic device includes a substrate layer, and that substrate layer includes a conductive substrate layer. The device also includes a first photovoltaic cell disposed on the conductive substrate layer, a conductive layer disposed on the first photovoltaic cell, and a second photovoltaic cell disposed on the conductive layer. The second photovoltaic cell includes a laser-treated portion.

Implementations of the device may include one or more of the following features. At least one photovoltaic cell can be a thin film photovoltaic cell. The first and second photovoltaic cells may be silicon photovoltaic cells. The first photovoltaic cell may be configured to substantially absorb a first wavelength of incident sunlight upon the device, and the second photovoltaic cell may be configured to substantially absorb a second wavelength of incident sunlight upon the device that is longer than the first wavelength. The substrate layer may be flexible. In some implementations, the laser-treated portion of the device is irradiated with a pulsed laser source. The irradiating may be performed with femtosecond, picosecond, or nanosecond pulsed laser radiation. The irradiating may further be performed in an inert environment. The device may include the feature wherein the irradiating is performed in an environment that contains a dopant chemical species. The dopant species may include a solid, liquid, or gas. In some implementations, the first photovoltaic cell includes a laser treated portion. The device may further include the feature wherein the second wavelength of incident light can pass substantially unabsorbed through the first photovoltaic cell. In some implementations, the second photovoltaic cell may be a thin film photovoltaic cell with quantum efficiency greater than 80% for light wavelengths longer than 900 nanometers. In other implementations, the second photovoltaic cell may be a thin film photovoltaic cell with quantum efficiency greater than 80% for light wavelengths longer than 800 nanometers. In yet other implementations, the second photovoltaic cell may be a thin film photovoltaic cell with quantum efficiency greater than 80% for light wavelengths longer than 700 nanometers.

The device may include the feature wherein the first photovoltaic cell comprises a P-N junction. In other implementations, the first photovoltaic cell may include a P-i-N junction. The device may also include the feature wherein the second photovoltaic cell comprises a P-N junction. In other implementations, the second photovoltaic cell may include a P-i-N junction.

The device may include the feature wherein the second photovoltaic cell exhibits an absorptance greater than 80% for light wavelengths longer than 800 nanometers. In other implementations, the second photovoltaic cell may exhibit an absorptance greater than 90% for light wavelengths longer than 800 nanometers. The device may also be laser annealed subsequent to the irradiating of the laser treated portion.

In general, in another embodiment of the present invention, a photovoltaic device is provided. The photovoltaic device includes a substrate layer, the substrate layer comprising a conductive substrate layer. The device also includes a first p-type layer disposed on the conductive substrate layer, a first i-type layer disposed on the first p-type layer, a first n-type layer disposed on the first i-type layer, a conductive layer disposed on the first n-type layer, a second p-type layer disposed on the conductive layer, a second i-type layer disposed on the second p-type layer, and a second n-type layer disposed on the second i-type layer, wherein the second n-type layer comprises a laser-treated portion.

The technique used to make this type of single-material, combination photovoltaic device can also be extended to multi-material, combination photovoltaic devices for further performance benefits.

Specific examples of applications of the present methods and apparatus include thin-film photovoltaic power generation.

Other uses for the methods and apparatus given herein can be developed by those skilled in the art upon comprehending the present disclosure.

### BRIEF DESCRIPTION OF THE DRAWINGS

For a fuller understanding of the nature and advantages of the present invention, reference is being made to the following detailed description of preferred embodiments and in connection with the accompanying drawings, in which:

FIG. 1 illustrates a cross section of an exemplary multi-junction thin-film solar cell architecture according to some embodiments hereof;

FIG. 2 illustrates an exemplary system for manufacturing an exemplary multi-junction thin film solar cell including a laser processed silicon layer according to one embodiment of the present invention;

FIG. 3 illustrates a flow chart of various stages of an exemplary method of making a multi-junction thin film photovoltaic device according to one embodiment of the present invention

FIG. 4 presents exemplary quantum efficiency data plots of four different types of solar cells.

### DETAILED DESCRIPTION

As disclosed above, the present invention describes systems and articles of manufacture for providing multi-junction thin-film semiconductor photovoltaic devices and methods for making and using the same. In a preferred embodiment the multi-junction thin-film semiconductor device can be laser processed to enhance absorption characteristics of the device.

Some or all embodiments hereof include a portion comprising a semiconductor material, for example silicon, which is irradiated by a short pulse laser to create modified micro-structured surface morphology. The laser processing can be the same or similar to that described in U.S. Pat. No. 7,057,256. The laser-processed semiconductor is made to have advantageous light-absorbing properties. In some cases this type of material has been called “black silicon” due to its visually darkened appearance after the laser processing and because of its enhanced absorption of visible and infrared radiation compared to other forms of silicon.

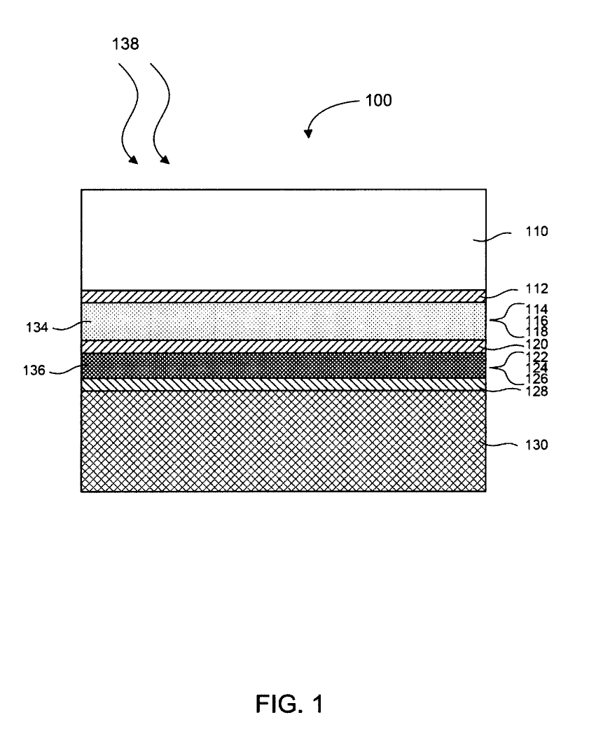

We now turn to a description of an exemplary multi-junction thin film photovoltaic device as shown in FIG. 1. More specifically, FIG. 1 illustrates a cross-section of an exemplary embodiment of a photovoltaic device having a plurality of junctions and a laser processed layer. For purposes of this embodiment, the semiconductor material can be silicon. One skilled in the art will appreciate that other semiconductor materials may be used to achieve similar results. The photovoltaic device 100 may include a substrate layer 110, a conductive substrate layer 112, a p-type thin film silicon layer 114, an i-type or intrinsic thin film silicon layer 116, an n-type thin film silicon layer 118, a conductive interlayer 120, a p-type thin film silicon layer 122, an i-type thin film silicon layer 124, a laser processed n-type thin film silicon layer 126, a conductive electrical contact layer 128, and an encapsulant layer 130.

The substrate layer 110 may be comprised of a suitable material such as a polymer or glass. Depending on the material the substrate may have flexible and/or structural characteristics. Other materials, known to those skilled in the art, that are at least partially transparent to light having wavelengths greater than 300 nm may be used. The structural substrate layer 110 provides a base for the conductive substrate layer 112. The conductive substrate layer 112 may be of any suitable material such as aluminum or a transparent conductive oxide layer. The p-type thin film silicon layer 114, can be in contact with the substrate layer 110. The p-type thin film silicon layer 114 is an appropriate thickness for the application, such as 1-5000 nm thick, particularly 5 to 100 nm. An intrinsic or i-type thin film silicon layer 116 of appropriate thickness, e.g. 0-5000 nm thick, particularly 500 to 1000 nm, can be disposed on top of the p-type silicon layer 114. In some embodiments, an i-type silicon layer may not be present. The top surface of the i-type thin film silicon layer 116 can be in contact with the n-type thin film silicon layer 118. Although the preferred embodiment uses thin film silicon layers, non thin film layers may also be used. The n-type laser processed silicon layer 118 may be of an appropriate thickness for a specific application, for example, between 10-5000 nm thick, particularly 100-500 nm. The three layers, p-type 114, i-type 116, n-type 118, may comprise a first single photovoltaic cell 134 having extended wavelength properties. The first single photovoltaic cell 134 is composed of amorphous silicon. A conductive layer 120, may be disposed between the first photovoltaic cell 134 and a second photovoltaic solar cell 136. Conductive layer 120 may be of any suitable material such as zinc oxide or a transparent conductive oxide layer. The second photovoltaic cell 136 may comprise the p-type layer 122, i-type layer 124, and n-type layer 126. The second photovoltaic cell 136 is composed of microcrystalline silicon. The p-type thin film silicon layer 122 which can be in contact with conductive layer 120 and i-type thin film silicon layer 124. The p-type thin film silicon layer 122 is an appropriate thickness for the application, such as 1-5000 nm thick, particularly 5 to 500 nm. An intrinsic or i-type thin film silicon layer 124 of appropriate thickness, e.g. 0-5000 nm thick, particularly 500 to 1000 nm, may be disposed between and may be in contact with the p-type thin film silicon layer 122 and an n-type laser processed silicon layer 126. In some embodiments, an i-type silicon layer may not be present. The top surface of the i-type thin film silicon layer 124 may be in direct contact with the p-type thin film silicon layer 126. As previously mentioned, the n-type thin film silicon layer 126 may be in contact with the i-type silicon layer 124 and a conductive layer 128, and may be of an appropriate thickness for a specific application, for example, between 10-5000 nm thick, particularly 100-500 nm. In addition, the n-type silicon layer may be a laser processed layer to enhance the absorption properties of the layer and ultimately the overall absorption properties of the device 100. An encapsulant layer 130 can be comprised of a material that is at least partially transparent to wavelengths from about 300 nm to about 1300 nm and may be in contact with conductive layer 128. Incidentally, the conductive layer 128 can be comprised of any electrically and/or thermally conductive material, i.e. metal, alloy or conductive transparent oxide materials. In this configuration incident sunlight 138 may strike and pass through either the substrate layer 110 or the encapsulant layer 130 of the photovoltaic device 100 whereby at least portions of various wavelengths of the sunlight pass through the device can be absorbed by the layers 114, 116, 118, 122, 124, and 126 of the photovoltaic device 100.

The incident sunlight 138 includes relatively shorter wavelengths of light which are absorbed and converted into photocarriers within the p-type thin film silicon layer 114, i-type thin film silicon layer 116 and n-type thin film silicon layer 118. Longer wavelengths of incident sunlight 138 can pass unabsorbed through the first photovoltaic cell 134, such that the longer wavelengths of light may be absorbed in the second photovoltaic cell 136, in the laser processed silicon n-type layer 126, the i-type layer 124, and the p-type layer 122. Thus, the n-type laser processed silicon layer 126 may perform as a back-stop for longer wavelength light.

In addition to absorption, high energy conversion requires that photocarriers are created and collected efficiently.

Electrical contacts (not shown) or ohmic contacts may be included in the present invention to aid in the transfer of electrical energy. The electrical contacts may comprise any metal or alloy that enables the flow of electricity.

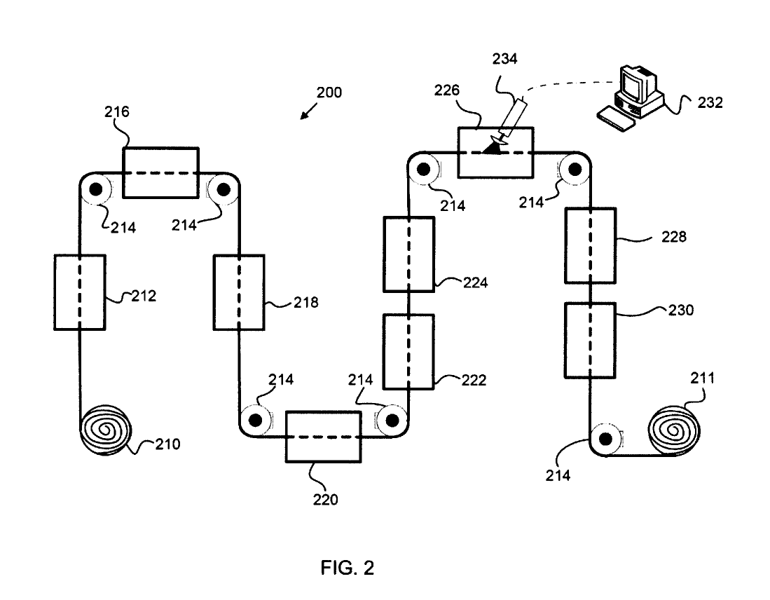

FIG. 2 illustrates an exemplary method and apparatus 200 for laser processing silicon in a thin film multi junction solar cell. The laser processing method and apparatus 200 may include appropriate equipment and processes to utilize a conveyor belt or a roll-to-roll process for laser processing the silicon for thin film solar cells. Thus, a thin layer of silicon may be deposited on a flexible substrate and wound onto a roll for further processing. The substrate may be configured with a conductive material. The thin film layer of silicon deposited onto a conductive substrate can be provided in an automated process such as roll-to-roll to be laser processed with femtosecond laser pulses in a gas environment that contains a desired dopant chemical species (such as but not limited to nitrogen, phosphorous, sulfur, etc). This laser processing can be accomplished by rastering a laser across the silicon surface or by using multiple laser beams. In one embodiment, laser processing of the silicon layer is performed with a curtain of laser light using one or more cylindrical lenses so that entire lines of silicon are laser processed as they pass beneath the laser light in a roll to roll or conveyor belt process.

The laser processing is comprised of illuminating the desired silicon layer with a plurality of short laser pulses so as to uniformly improve the long wavelength quantum efficiency of the laser processed layer. In one embodiment, the laser pulses are at high enough energy to be above the melting threshold of the irradiated semiconductor. The number of laser pulses can vary from 1 per area to many hundreds per area so as to sufficiently alter the semiconductor surface to ensure increased quantum efficiency as compared to amorphous silicon at wavelengths longer than 750 nm. The ambient environment during laser irradiation can include a desired dopant gas, liquid or solid or an inert environment. The inert environment is preferred in the embodiment where the dopant species of the laser processed layer is included by chemical vapor deposition.

In a preferred embodiment, a substrate comprised of a glass supporting substrate, a thin transparent conductive layer, a layer of thin p-doped hydrogen passivated amorphous silicon (aSi:H), a layer of intrinsic amorphous silicon (aSi:H), a layer of n-doped silicon (aSi:H), a thin transparent conductive layer, a layer of thin p-doped microcrystalline silicon, and a layer of i-doped microcrystalline silicon is prepared for laser processing. The intrinsic microcrystalline silicon layer is then irradiated with between 1 and 50 laser pulses of duration in between 20 fs and 750 fs and at a fluence between 1 kJ/m2 and 6 kJ/m2. The laser irradiation is carried out in an ambient environment that contains a preferred n-type dopant species (such as phosphorous, sulfur, etc.). However, it can be understood by those skilled in the art that the laser process can also be performed to introduce a p-type dopant into a structure that is comprised of an n-type layer covered by an intrinsic silicon layer. In addition, the dopant species in the laser processed layer can be introduced into the semiconductor substrate prior to laser irradiation.

Subsequent to the laser processing of the silicon layer an anneal process is carried out to activate the dopant species implanted during laser processing. This may be carried out through any means of annealing (i.e. Rapid thermal annealing, laser annealing, furnace annealing etc). At this point the laser processed silicon is a doped n-type or p-type layer depending on the dopant species used during laser processing.

Manufacturing thin film multi-junction photovoltaic cells with laser processed portions must be commercially feasible, and should therefore conform to existing methods of manufacturing thin film flexible solar cells. The problem however is that the multi junction device with a amorphous layer cannot be traditionally annealed without damaging the amorphous layer. Thus the current method discloses laser annealing subsequent to the laser processing which will not thermally affect the amorphous layer.

Referring to FIG. 2, with further reference to FIG. 1, various stages of a process 200 are shown for manufacturing a multi junction thin film solar cell including a laser processed silicon layer. The multi junction photovoltaic device 100 in FIG. 1 is manufactured upside down such that the top transparent substrate layer 110 and conductive substrate layer 112 are provided in the process 200 on a flexible roll 210. During the manufacturing process 200, the top substrate layers of the photovoltaic device 100 become the bottom base layer from which the rest of the device 100 is built upon. The process 200 includes providing the flexible substrate layers 110,112, from the substrate roll 210 to the p-doped silicon layer deposition process step 212, where an appropriate thickness of p-doped silicon 114 is disposed on the conductive substrate layer 112. The process 200 also includes a plurality of roller elements 214 to facilitate the transport of the flexible substrate through the process 200. The process 200 further includes a depositing of an intrinsic layer of silicon step 216, where a layer of silicon 116 of appropriate thickness is disposed on top of the p-type layer 114. The n-doped silicon layer deposition step 218 disposes an n-type thin film silicon layer 118 layer of appropriate thickness onto the first i-type layer 116. Next, the conductive interlayer step 220 disposes a transparent conducting layer 120 on top of the first n-type thin film silicon layer 118. The second p-doped silicon layer deposition process step 222 places the second p-type layer 122, of appropriate thickness on top of the conductive interlayer 120. The second deposition of an intrinsic layer of silicon step 224 places the second i-type layer 124 on top of the second p-type layer 122. The laser processing step 226, includes directing an appropriately sized laser beam or curtain of laser light onto the silicon in an automated manner as the silicon layer passes through an appropriate environment to introduce n-type dopant during laser irradiation. The laser processing can be accomplished by the laser assembly 234 via rastering the laser across the silicon surface or by using multiple laser beams. The laser assembly 234 may be operatively coupled to a control computer 232 which may control such variables as frequency, duration, fluence, and targeting of the laser assembly 234 as well as other system variables such as the linear speed of the flexible substrate supply and take-up rolls 210, 211. An automated process may be considered a process which can be properly set up by a user to utilize control equipment such as a computer to control systems, machinery, and processes, thereby reducing the need for human intervention.

In one embodiment, laser processing of the silicon layer is performed with a curtain of laser light using one or more cylindrical lenses so that substantially all of the width of the web of flexible silicon is laser processed as it passes beneath the laser light in a roll to roll or conveyor belt process. In some embodiments, one laser beam may be focused to cover the width of the silicon layer and in other embodiments, multiple laser beams may be focused to cover the width of the silicon layer.

Subsequent to the laser processing step 226, the process 200 includes laser annealing 228 the processed silicon to activate the dopant species implanted during laser processing 226 without damaging the previously deposited amorphous photovoltaic cell 134. The final conducting layer deposition step 230 may be configured to deposit a conductive electrical contact layer 128 on top of the laser processed n-type thin film silicon layer 126. Although not shown, an encapsulant layer deposition step may be included before the take up roll 211.

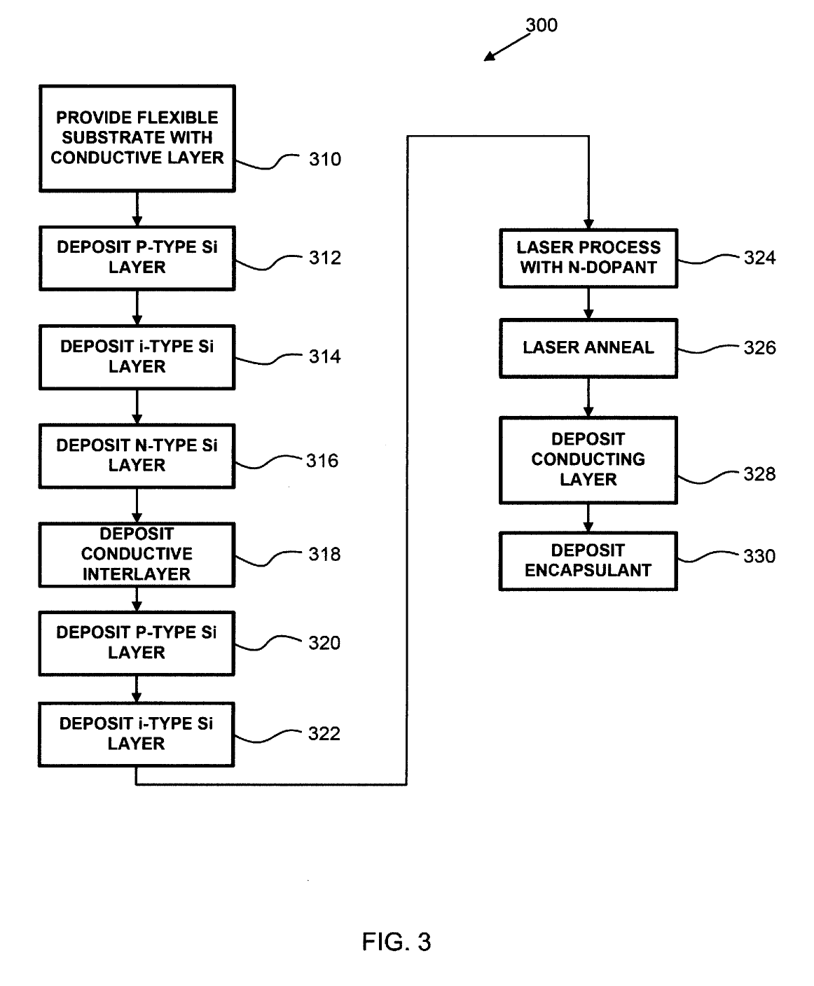

Referring to FIG. 3, with further reference to FIGS. 1 and 2, various stages of a process 300 are shown for manufacturing a multi-junction thin film solar cell including a laser processed silicon layer. The process 300 includes providing a thin film layer of silicon deposited onto a substrate including an appropriate transparent conductive layer 310, depositing a thin layer of amorphous silicon 312 onto the conductive layer so that there is a layer of p-doped silicon on top of the conductive layer, depositing an intrinsic layer 314 on top of the p-doped silicon layer, and depositing a thin layer of n-doped amorphous silicon 316 on top of the first intrinsic layer to form an amorphous silicon photovoltaic cell 134 with a P-i-N junction. The process 300 also includes depositing a conductive interlayer 318 on top of the n-doped amorphous silicon layer, depositing a layer of thin p-doped microcrystalline silicon 320 on top of the transparent conductive interlayer, depositing a layer of i-doped microcrystalline silicon 322 on top of the p-doped microcrystalline silicon layer, and laser processing the intrinsic microcrystalline silicon layer 324 in an ambient environment that contains an n-type dopant species. The process 300 includes subsequently laser annealing 326 to activate the dopant species implanted during laser processing while avoiding causing thermal damage to the amorphous silicon photovoltaic cell 134.

The process 300 also includes depositing a conducting back contact layer 328 on top of the laser processed microcrystalline silicon layer, and depositing an encapsulant layer 330 on top of the back electrical contact layer.

As stated and described herein, the thin film systems and the method of manufacturing thereof produce a thin film system with greater quantum efficiencies. In particular, quantum efficiency measures the efficiency of light power that is converted to electric power. The invention described herein achieves the following quantum efficiencies: quantum efficiencies greater than about 85% for wavelengths between about 700 nm and 1050 nm; quantum efficiencies greater than about 85% in one wavelength between about 900 nm and 1100 nm; quantum efficiencies greater than about 90% in one wavelength beyond about 700 nm for a thin film; quantum efficiencies greater than about 80% in one wavelength beyond about 900 nm for a thin film of silicon.

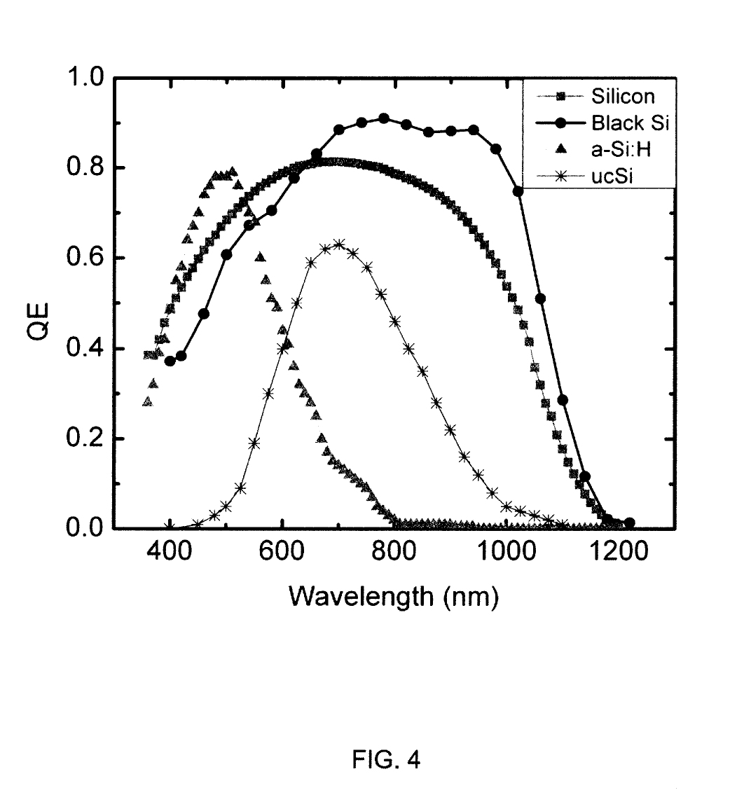

FIG. 4 shows quantum efficiency curves for four photovoltaic devices. A typical amorphous silicon solar cell, a typical high efficiency monocrystalline solar cell, a typical microcrystalline cell (μcSi), and a short pulse laser processed silicon solar cell (Black Si) as disclosed herein. The laser processed solar cell has significantly increased quantum efficiency as compared to the amorphous silicon and microcrystalline solar cells for wavelengths longer than 700 nm and has increased quantum efficiency as compared to a high efficiency monocrystalline solar cell or a microcrystalline solar cell for wavelengths longer than 800 nm.

The present invention should not be considered limited to the particular embodiments described above, but rather should be understood to cover all aspects of the invention as fairly set out in the attached claims. Various modifications, equivalent processes, as well as numerous structures to which the present invention may be applicable, will be readily apparent to those skilled in the art to which the present invention is directed upon review of the present disclosure. The claims are intended to cover such modifications.

1. A photovoltaic device comprising:
a substrate layer, the substrate layer comprising a conductive substrate layer;
a first photovoltaic cell disposed on the conductive substrate layer;
a conductive layer disposed on the first photovoltaic cell;
a second photovoltaic cell disposed on the conductive layer, the second photovoltaic cell comprising a laser-treated portion.

2. The device of claim 1, wherein at least one photovoltaic cell is a thin film photovoltaic cell.

3. The device of claim 1, wherein the first and second photovoltaic cells are silicon photovoltaic cells.

4. The device of claim 1 wherein the first photovoltaic cell is configured to substantially absorb a first wavelength of incident sunlight upon the device, and the second photovoltaic cell is configured to substantially absorb a second wavelength of incident sunlight upon the device that is longer than the first wavelength.

5. The device of claim 1, wherein the substrate layer is flexible.

6. The device of claim 1, wherein the laser-treated portion is irradiated with a pulsed laser source.

7. The device of claim 6, wherein the irradiating comprises irradiating with femtosecond pulsed laser radiation.

8. The device of claim 6, wherein the irradiating comprises irradiating with picosecond pulsed laser radiation.

9. The device of claim 6, wherein the irradiating comprises irradiating with nanosecond pulsed laser radiation.

10. The device of claim 6, wherein the irradiating is performed in an inert environment.

11. The device of claim 6, wherein the irradiating is performed in an environment that contains a dopant chemical species.

12. The device of claim 1, wherein the first photovoltaic cell comprises a laser treated portion.

13. The device of claim 4, wherein the second wavelength of incident light can pass substantially unabsorbed through the first photovoltaic cell.

14. The device of claim 4, wherein the second photovoltaic cell comprises a thin film photovoltaic cell with quantum efficiency greater than 80% for light wavelengths longer than 900 nanometers.

15. The device of claim 4, wherein the second photovoltaic cell comprises a thin film photovoltaic cell with quantum efficiency greater than 80% for light wavelengths longer than 800 nanometers.

16. The device of claim 4, wherein the second photovoltaic cell comprises a thin film photovoltaic cell with quantum efficiency greater than 80% for light wavelengths longer than 700 nanometers.

17. The device of claim 1, wherein the first photovoltaic cell comprises a P-N junction.

18. The device of claim 1, wherein the first photovoltaic cell comprises a P-i-N junction.

19. The device of claim 1, wherein the second photovoltaic cell comprises a P-N junction.

20. The device of claim 1, wherein the second photovoltaic cell comprises a P-i-N junction.

21. The device of claim 1, wherein the second photovoltaic cell exhibits an absorptance greater than 80% for light wavelengths longer than 800 nanometers.

22. The device of claim 1, wherein the second photovoltaic cell exhibits an absorptance greater than 90% for light wavelengths longer than 800 nanometers.

23. The device of claim 11, wherein the device is laser annealed subsequent to the irradiating.

24. A photovoltaic device comprising:
a substrate layer, the substrate layer comprising a conductive substrate layer;
a first p-type layer disposed on the conductive substrate layer;
a first i-type layer disposed on the first p-type layer;
a first n-type layer disposed on the first i-type layer;
a conductive layer disposed on the first n-type layer;
a second p-type layer disposed on the conductive layer;
a second i-type layer disposed on the second p-type layer;
a second n-type layer disposed on the second i-type layer, wherein the second n-type layer comprises a laser-treated portion.
